(19) United States
(12) Patent Application Publication
(10) Pub. No.: US 2016/0155908 A1
(43) Pub. Date: Jun. 2, 2016

(54) COA SUBSTRATE AND MANUFACTURING METHOD THEREOF

(71) Applicant: SHENZHEN CHINA STAR OPTOELECTRONICS TECHNOLOGY CO., LTD., Shenzhen, Guangdong (CN)

(72) Inventor: Liwang Song, Shenzhen (CN)

(21) Appl. No.: 14/417,287

(22) PCT Filed: Dec. 10, 2014
(86) PCT No.: PCT/CN2014/093418

§ 371 Date: Jan. 26, 2015

(30) Foreign Application Priority Data
Dec. 1, 2014 (CN) 201410718424.1

(51) Int. Cl. H01L 33/50; H01L 27/12

(52) U.S. Cl. CPC H01L 33/50; H01L 27/1248; H01L 27/1222; H01L 27/1262

(57) ABSTRACT

A color filter on array (COA) substrate and a manufacturing method thereof are provided. The method comprises: forming a first metal layer, a gate insulation layer, an active layer, an ohmic contact layer, a second metal layer, a first passivation layer, a color resist layer, a second passivation layer, a through hole, and a transparent conductive layer on a substrate in order; and forming a spacer and/or a black matrix on a surface of the COA substrate, and filling a material of the spacer or an organic material of the black matrix into the through hole.

### FIELD OF THE INVENTION

The present invention relates to a technological field of liquid crystal displays, and more particularly to a color filter on array (COA) substrate and a manufacturing method thereof.

### BACKGROUND OF THE INVENTION

A COA (color filter on array) substrate is provided by manufacturing a color filter onto an array substrate. Refer now to FIG. 1, which is a structural schematic view of a COA substrate according to a conventional technology. As shown in FIG. 1, a conventional COA substrate comprises a substrate 111, a first metal layer 112, a gate insulation layer 113, an active layer 114, an ohmic contact layer 115, a second metal layer 116, a first passivation layer 117, a color resist layer 118, a second passivation layer 119, and a transparent conductive layer 120. The transparent conductive layer 120 comprises a pixel electrode, and the pixel electrode is connected to a drain electrode area of the second metal lay by a through hole 121 which passes through the color resist layer 118 and the second passivation layer 119.

However, the conventional COA substrate is manufactured under a high temperature process, and the high temperature causes an organic material of the color resist layer to be volatilized into air bubbles. The through hole 121 has an unnecessary space existing inside, so that the produced air bubbles are reserved inside the through hole. When the display is turn on, since the air bubbles occupy some of the space of the liquid crystal molecules, the liquid crystal molecules cannot reach the place where the air bubbles are staying, so that the display effect is influenced.

Hence, it is necessary to provide a COA substrate and a manufacturing method thereof which solves the problems existing in the conventional technologies.

### SUMMARY OF THE INVENTION

The object of the present invention is to provide a color filter on array (COA) substrate and a manufacturing method thereof which solve a technical problem existing in the conventional technology in which air bubbles are reserved inside a through hole influencing the display effect.

For solving the above-mentioned technological problems, the present invention constructs a COA substrate, which comprises:

a substrate;

a first metal layer positioned on the substrate and comprising a gate electrode area of a thin film transistor;

a gate insulation layer partially positioned on the first metal layer and used to separate the first metal layer and a second metal layer;

an active layer partially positioned on the gate insulation layer and used to form a channel;

an ohmic contact layer positioned on the active layer;

the second metal layer positioned on the ohmic contact layer and comprising a drain electrode area and a source electrode of the thin film transistor;

a first passivation layer positioned on the second metal layer and used to separate the second metal layer and a color resist layer;

the color resist layer positioned on the first passivation layer and used to form color resists;

a second passivation layer positioned on the color resist layer and including a through hole to be connected to the drain electrode of the second metal layer;

a transparent conductive layer positioned on the second passivation layer and inside the through hole; and

a spacer positioned on a surface of the COA substrate, wherein a material of the spacer is filled into the through hole.

In the COA substrate according to the present invention, a predetermine amount of the material of the spacer is filled into the through hole, so that the predetermine amount of the material of the spacer is used to flatten the surface of the COA substrate.

In the COA substrate according to the present invention, the surface of the COA substrate is provided with the material of the spacer, and the material of the spacer is used to form the spacer.

In the COA substrate according to the present invention, the material of the second passivation layer is an organic and transparent material.

The present invention constructs a manufacturing method of the COA substrate, which comprises:

forming a first metal layer on a substrate, and graphing the first metal layer to form a gate electrode;

forming a gate insulation layer on the gate electrode and parts of the substrate which is uncovered by the gate electrode;

forming an active layer on the gate insulation layer;

forming an ohmic contact layer on the active layer;

forming a second metal layer on the ohmic contact layer, and graphing the second metal layer to form a drain electrode and a source electrode;

forming a first passivation layer on the second metal layer;

forming a color resist layer on the first passivation layer;

forming a second passivation layer on the color resist layer;

forming a through hole on the second passivation layer to connect the drain electrode;

forming a transparent conductive layer on the second passivation layer and inside the through hole; and

forming a black matrix on a surface of the COA substrate and filling a material of the black matrix inside the through hole.

In the manufacturing method of the COA substrate according to the present invention, the step of filling a material of the black matrix inside the through hole includes: filling a material of the black matrix inside the through hole until the surface of the COA substrate is flat.

In the manufacturing method of the COA substrate according to the present invention, the step of forming a black matrix on a surface of the COA substrate includes: coating the material of the black matrix on the surface of the COA substrate; and forming the black matrix by graphing the material of the black matrix.

In the manufacturing method of the COA substrate according to the present invention, after the step of forming a transparent conductive layer on the second passivation layer and inside the through hole, the method further includes:

forming a spacer and a black matrix on the surface of the COA substrate; and filling the material of the black matrix into the through hole.

In the manufacturing method of the COA substrate according to the present invention, the step of forming a spacer and a black matrix on the surface of the COA substrate includes: coating the material of the black matrix on the surface of the COA substrate; and forming the black matrix by graphing the material of the black matrix.

In the manufacturing method of the COA substrate according to the present invention, the step of forming a second passivation layer on the color resist layer includes: the second passivation layer is formed on the color resist layer by a coating method, wherein the material of the second passivation layer is an organic and transparent material.

The present invention further constructs a COA substrate, which comprises:

a substrate;

a first metal layer positioned on the substrate and comprising a gate electrode area of a thin film transistor;

a gate insulation layer partially positioned on the first metal layer and used to separate the first metal layer and a second metal layer;

an active layer partially positioned on the gate insulation layer and used to form a channel;

an ohmic contact layer positioned on the active layer;

the second metal layer positioned on the ohmic contact layer and comprising a drain electrode area and a source electrode of the thin film transistor;

a first passivation layer positioned on the second metal layer and used to separate the second metal layer and a color resist layer;

the color resist layer positioned on the first passivation layer and used to form color resists;

a second passivation layer positioned on the color resist layer and including a through hole to be connected to the drain electrode of the second metal layer;

a transparent conductive layer positioned on the second passivation layer and inside the through hole; and

a spacer and a black matrix positioned on a surface of the COA substrate, wherein a material of the black matrix is filled into the through hole.

In the COA substrate according to the present invention, a predetermine amount of the material of the black matrix is filled into the through hole, so that the predetermine amount of the material of the black matrix is used to flatten the surface of the COA substrate.

In the COA substrate according to the present invention, the surface of the COA substrate is provided with the material of the black matrix, and the material of the black matrix is used to form the spacer.

In the COA substrate according to the present invention, the material of the second passivation layer is an organic and transparent material.

In the COA substrate according to the present invention, the material of the black matrix is a black photoresist.

The present invention provides a COA substrate and a manufacturing method thereof, wherein when forming a spacer and/or a black matrix, a material of the spacer or the black matrix is filled into a through hole, so as to improve the display effect.

### DESCRIPTION OF THE DRAWINGS

FIG. 1 is a structural schematic view of a COA substrate according to a conventional technology;

FIG. 2 is a structural schematic view of a COA substrate according to a first embodiment of the present invention;

FIG. 3 is a structural schematic view of a COA substrate according to a second embodiment of the present invention; and

FIG. 4 is a structural schematic view of a COA substrate according to a third embodiment of the present invention.

### DETAILED DESCRIPTION OF THE PREFERRED EMBODIMENTS

The foregoing objects, features, and advantages adopted by the present invention can be best understood by referring to the following detailed description of the preferred embodiments and the accompanying drawings. Furthermore, the directional terms described in the present invention, such as upper, lower, front, rear, left, right, inner, outer, side, etc., are only directions with reference to the accompanying drawings, so that the used directional terms are used to describe and understand the present invention, but the present invention is not limited thereto. In the drawings, units with similar structures use the same numerals.

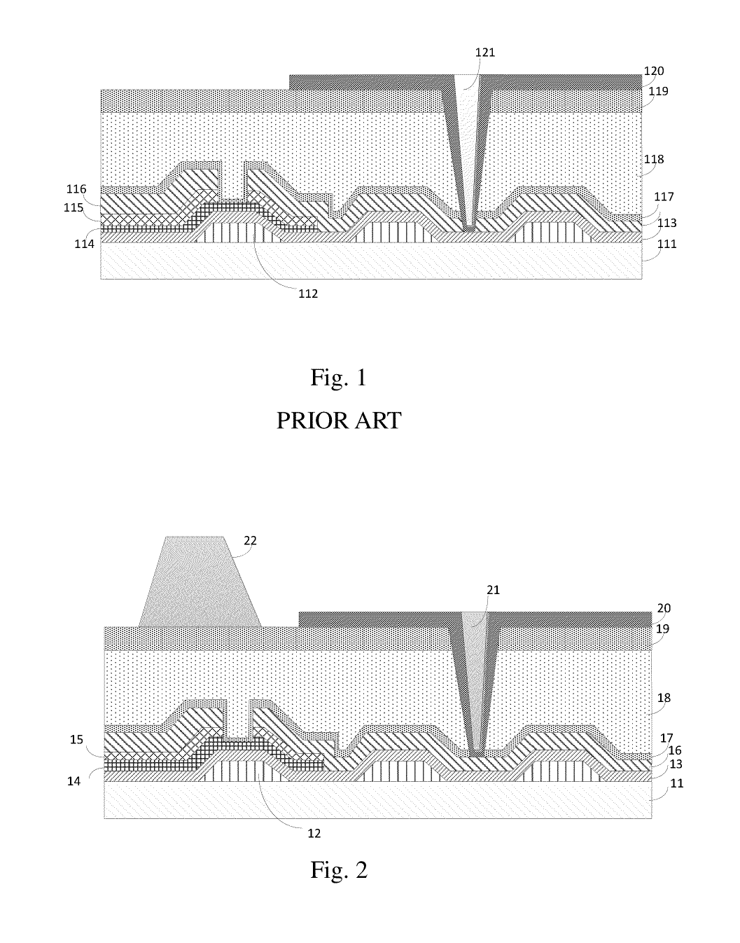

Refer now to FIG. 2, which is a structural schematic view of a color filter on array (COA) substrate according to a first embodiment of the present invention.

As shown in FIG. 2, a COA substrate according to the present invention comprises a substrate 11, a first metal layer 12, a gate insulation layer 13, an active layer 14, an ohmic contact layer 15, a second metal layer 16, a first passivation layer 17, a color resist layer 18, a second passivation layer 19, and a transparent conductive layer 20.

The first metal layer 12 is located on the substrate 11, and comprises a gate electrode area of a thin film transistor. The gate electrode is formed by graphing the first metal layer 12, and the other part of the first metal layer 12 excluding the gate electrode is etched in the process. For separating the first metal layer 12 and the second metal layer 16 and separating the first metal layer 12 and the active layer 14, the gate insulation layer 13 is disposed on the first metal layer 12, but the gate insulation layer 13 is disposed on the first metal layer 12 only in the gate electrode area, the rest of the gate insulation layer 13 is disposed on the substrate. The active layer 14 is partially located on the gate insulation layer 13, and is used to form a channel between a drain electrode and a source electrode of the thin film transistor. The ohmic contact layer 15 is located on the active layer 14, and is used to conduct the source electrode and the drain electrode when the gate electrode of the thin film transistor is turn off. The material of the ohmic contact layer can be silicon nitride.

The second metal layer 16 is located on the ohmic contact layer 15, and comprises a drain electrode area and a source electrode are of the thin film transistor. The drain electrode and the source electrode are formed by graphing the second metal layer 16, and the other part of the second metal layer is etched in the process.

The first passivation layer 17 is located on the second metal layer 16, and is used to separate the drain electrode and the source electrode from the color resist layer 18 respectively. The color resist layer 18 is located on the first passivation layer 17, wherein color resists are formed by graphing the color resist layer 18. The second passivation layer 19 is located on the color resist layer 18, and is used to separate the color resist layer 18 and the transparent conductive layer 20. The second passivation layer 19 is provided with a through hole 21 which is connected to the drain electrode of the second metal layer 16. The through hole 21 passes through the color resist layer 18, the second passivation layer 19, and the first passivation layer 17. The transparent conductive layer 20 is located on the second passivation layer 19 (only partially covering the second passivation layer 19), and comprises a pixel electrode. The pixel electrode is connected to the drain electrode by the through hole 21. The material of the second passivation layer 19 can be an organic and transparent material.

A surface of the COA substrate is further provided with a spacer 22, wherein the through hole 21 has the material of the spacer filled inside. Specifically, the spacer 22 is disposed on a part of second passivation layer 19 which is uncovered by the transparent conductive layer 20, and a predetermine amount of the material of the spacer is filled into the through hole, so that the predetermine amount of the material of the spacer is used to flatten the surface of the COA substrate. When the surface of the COA substrate is more flat, the diffusion of the liquid crystal molecules is more flat. This is advantageous to obtaining the best liquid crystal amount in the manufacturing process of the liquid crystal display panel (the required amount of liquid crystal molecules for reaching the best display effect of the liquid crystal display panel).

A manufacturing method of the above-mentioned COA substrate comprises:

S101: forming a first metal layer on a substrate, and graphing the first metal layer to form a gate electrode.

In the step S101, specifically, the first metal layer is exposed, developed, and etched to form a gate electrode by a mask with graphs, and the other part of the first metal layer 12 excluding the gate electrode is etched in the process. The material of the first metal layer 12 can be chromium, molybdenum, aluminum, or copper.

S102: forming a gate insulation layer on the gate electrode and the substrate which is uncovered by the gate electrode.

S103: forming an active layer on the gate insulation layer.

The active layer is used to form a channel between a drain electrode and a source electrode of the thin film transistor, and the material of the active layer is, for example, amorphous silicon.

S104: forming an ohmic contact layer on the active layer.

The material of the ohmic contact layer is possible to be Silicon Nitride.

S105: forming a second metal layer on the ohmic contact layer, and graphing the second metal layer to form a drain electrode and a source.

In the step S105, specifically, the second metal layer is exposed, developed, and etched to form the drain electrode and the source electrode of the thin film transistor by a mask with graphs, and the other part of the second metal layer excluding the drain electrode and the source electrode is etched in the process.

S106: forming a first passivation layer on the second metal layer.

The first passivation layer is used to separate the second metal layer from a color resist layer respectively.

S107: forming the color resist layer on the first passivation layer.

The material of the color resist layer is generally an organic material. For example, a negative photoresist. The color resist layer is exposed, developed, and etched to form color resists, wherein the color resists comprise red color resists, green color resists, and blue color resists.

S108: forming a second passivation layer on the color resist layer.

Usually, a vapor deposition method is adopted, and an inorganic material is provided on the color resist layer to protect the color resist layer, so as to effectively avoid the molecules of the color resists spreading into the liquid crystal molecules.

However, since the vapor deposition method is usually processed at a high temperature, when using the above-mentioned method to manufacture the second passivation layer, the organic materials of the color resist layer are volatilized into air bubbles. For avoiding this phenomenon, step S108 is preferably completed by:

S1081: selecting an organic and transparent material (for example, polymethyl methacrylate or polystyrene) to be the material of the second passivation layer, wherein the organic and transparent material is coated on the color resist layer to form the second passivation layer, so as to avoid the problem that the manufacture process is operated at a high temperature which causes the material of the color resist layer to be volatilized.

S109: forming a through hole on the second passivation layer to be connected to the drain electrode of the second metal layer.

The through hole is formed by a dry etching or wet etching process.

S1010: forming a transparent conductive layer on the second passivation layer and inside the through hole.

A sputter coating method can be used. The transparent conductive layer is formed on the passivation layer which has the through hole. The transparent conductive layer is provided with a pixel electrode. The pixel electrode is formed by a wet etching process. The through hole is used to connect between the pixel electrode and the drain electrode of the second metal layer, so that an electric current flows from the drain electrode to the pixel electrode.

S1011: forming a spacer on a surface of the COA substrate, and filling the through hole with a material of the spacer. Specifically, step S1011 comprises:

S201: coating the material of the spacer on the surface of the COA substrate.

When coating the material of the spacer, the through hole is filled with the material of the spacer at the same time, until the surface of the COA substrate is flat. That is, a thickness of the material of the spacer inside the through hole is equal to the height of the transparent conductive layer.

S202: forming the spacer by graphing the material of the spacer.

Since the material of the spacer is usually a photoresist, for example a transparent photoresist, the material of the spacer is exposed, developed, and etched to form the spacer by a mask. The spacer is formed at a location corresponding to the thin film transistor of the COA substrate.

In the embodiment, since the through hole is filled with the material of the spacer, inside of the through hole has no unnecessary space, and no air bubbles stay inside the COA substrate. This is advantageous in that the air bubbles are volatilized, so as to improve the display effect. In the embodiment, since the spacer is formed on the second passivation layer, meaning the through hole is filled and the spacer is formed, the manufacturing process is saved.

In the present invention, the through hole is filled when the spacer is formed, thereby avoiding the reservation of air bubbles, so as to improve the display effect and reduce manufacturing costs.

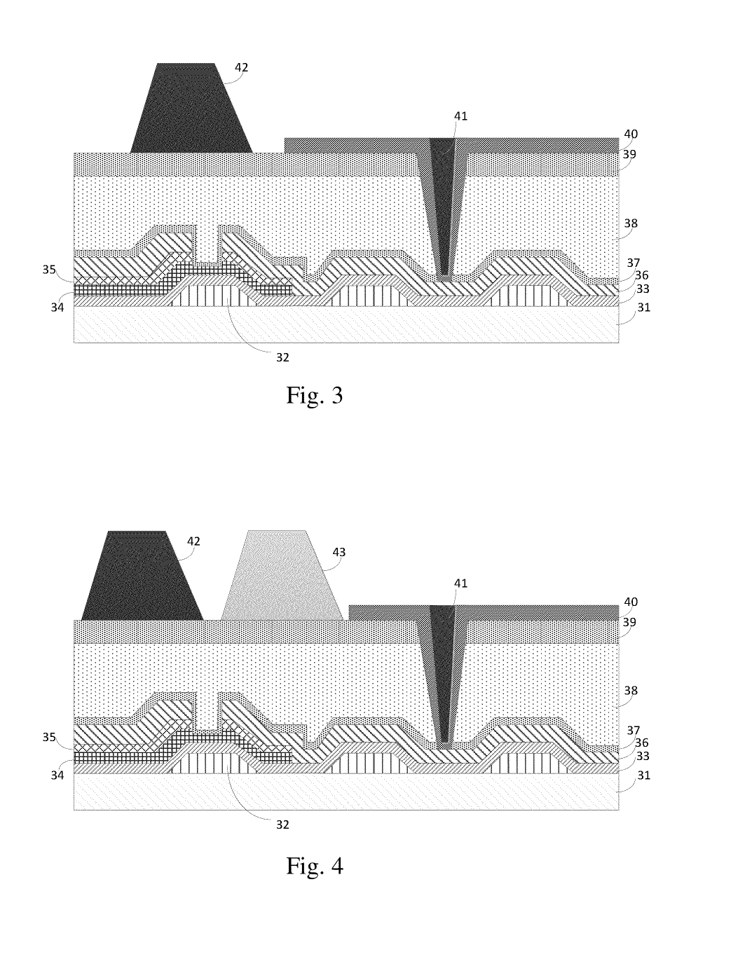

Refer now to FIG. 3, which is a structural schematic view of a COA substrate according to a second embodiment of the present invention.

As shown in FIG. 3, a COA substrate according to the present invention comprises a substrate 31, a first metal layer 32, a gate insulation layer 33, an active layer 34, an ohmic contact layer 35, a second metal layer 36, a first passivation layer 37, a color resist layer 38, a second passivation layer 39, and a transparent conductive layer 40.

The first metal layer 32 is located on the substrate 31, and comprises a gate electrode area of a thin film transistor. The gate electrode is formed by graphing the first metal layer 32, and the other part of the first metal layer 32 excluding the gate electrode is etched in the process. For separating the first metal layer 32 and the second metal layer 36 and separating the first metal layer 32 and the active layer 34, the gate insulation layer 33 is disposed on the first metal layer 32, but the gate insulation layer 33 is disposed on the first metal layer 32 only in the gate electrode area, the rest of the gate insulation layer 33 is disposed on the substrate. The active layer 34 is partially located on the gate insulation layer 33, and is used to form a channel between a drain electrode and a source electrode of the thin film transistor. The ohmic contact layer 35 is located on the active layer 34, and is used to conduct the source electrode and the drain electrode when the gate electrode of the thin film transistor is turned off. The material of the ohmic contact layer can be silicon nitride.

The second metal layer 36 is located on the ohmic contact layer 35, and comprises a drain electrode area and a source electrode area of the thin film transistor. The drain electrode and the source electrode are formed by graphing the second metal layer 36, and the other part of the second metal layer is etched in the process.

The first passivation layer 37 is located on the second metal layer 36, and is used to separate the drain electrode and the source electrode from the color resist layer 38 respectively. The color resist layer 38 is located on the first passivation layer 37, wherein color resists are formed by graphing the color resist layer 38. The second passivation layer 39 is located on the color resist layer 38, and is used to separate the color resist layer 38 and the transparent conductive layer 40. The second passivation layer 39 is provided with a through hole 41 which is connected to the drain electrode of the second metal layer 36. The through hole 41 passes through the color resist layer 38, the second passivation layer 39, and the first passivation layer 37. The transparent conductive layer 40 is located on the second passivation layer 39 (only partially covering the second passivation layer 39), and comprises a pixel electrode. The pixel electrode is connected to the drain electrode by the through hole 41. The material of the second passivation layer 39 can be an organic and transparent material.

A surface of the COA substrate is further provided with a black matrix 42, wherein the through hole 41 has the material of the black matrix filled inside. Specifically, the black matrix 42 is disposed on a part of second passivation layer 39 which is uncovered by the transparent conductive layer 40, and a predetermined amount of the material of the black matrix is filled into the through hole, so that the predetermine amount of the material of the black matrix is used to flatten the surface of the COA substrate. When the surface of the COA substrate is more flat, the diffusion of the liquid crystal molecules is more flat. This is advantageous to obtaining the best liquid crystal amount in the manufacturing process of the liquid crystal display panel (the required amount of liquid crystal molecules for reaching the best display effect of the liquid crystal display panel).

A manufacturing method of the above-mentioned COA substrate comprises:

S301: forming a first metal layer on a substrate, and graphing the first metal layer to form a gate electrode.

In step S301, specifically, the first metal layer is exposed, developed, and etched to form a gate electrode by a mask with graphs, and the other part of the first metal layer 32 excluding the gate electrode is etched in the process. The material of the first metal layer 32 can be chromium, molybdenum, aluminum, or copper.

S302: forming a gate insulation layer on the gate electrode and the substrate which is uncovered by the gate electrode.

S303: forming an active layer on the gate insulation layer.

The active layer is used to form a channel between a drain electrode and a source electrode of the thin film transistor, and the material of the active layer is, for example, amorphous silicon.

S304: forming an ohmic contact layer on the active layer.

The material of the ohmic contact layer can be silicon nitride.

S305: forming a second metal layer on the ohmic contact layer, and graphing the second metal layer to form a drain electrode and a source.

In step S305, specifically, the second metal layer is exposed, developed, and etched to form the drain electrode and the source electrode of the thin film transistor by a mask with graphs, and the other part of the second metal layer excluding the drain electrode and the source electrode is etched in the process.

S306: forming a first passivation layer on the second metal layer.

The first passivation layer is used to separate the second metal layer from a color resist layer respectively.

S307: forming the color resist layer on the first passivation layer.

The material of the color resist layer is generally an organic material, for example, a negative photoresist. The color resist layer is exposed, developed, and etched to form color resists, wherein the color resists comprises red color resists, green color resists, and blue color resists.

S308: forming a second passivation layer on the color resist layer.

Usually, a vapor deposition method is adopted, and an inorganic material is provided on the color resist layer to protect the color resist layer, so as to effectively avoid the molecules of the color resists spreading into the liquid crystal molecules.

However, since the vapor deposition method is usually processed at a high temperature, when using the above-mentioned method to manufacture the second passivation layer, organic materials of the color resist layer are volatilized into air bubbles. In order to avoid that phenomenon, step S308 is preferably completed by:

S3081: selecting an organic and transparent material (for example, polymethyl methacrylate or polystyrene) to be the material of the second passivation layer, wherein the organic and transparent material is coated on the color resist layer to form the second passivation layer, so as to avoid the problem caused by the manufacturing process being operated at a high temperature which causes the material of the color resist layer to be volatilized.

S309: forming a through hole on the second passivation layer to be connected to the drain electrode of the second metal layer.

The through hole is formed by a dry etching or wet etching process.

S3010: forming a transparent conductive layer on the second passivation layer and inside the through hole.

A sputter coating method can be used. The transparent conductive layer is formed on the passivation layer which has the through hole. The transparent conductive layer is provided with a pixel electrode. The pixel electrode is formed by a wet etching process. The through hole is used to connect between the pixel electrode and the drain electrode of the second metal layer, so that an electric current flows from the drain electrode to the pixel electrode.

S3011: forming a black matrix on a surface of the COA substrate, and filling the through hole with a material of the black matrix. Specifically, step S3011 comprises:

S401: coating the material of the black matrix on the surface of the COA substrate.

When coating the material of the black matrix, the through hole is filled with the material of the black matrix at the same time, until the surface of the COA substrate is flat. That is, a thickness of the material of the black matrix inside the through hole is equal to the height of the transparent conductive layer.

S402: forming the black matrix by graphing the material of the black matrix.

Since the material of the black matrix is usually a photoresist, for example a black photoresist, the material of the black matrix is exposed, developed, and etched to form the black matrix by a mask. The black matrix is formed in an opaque area, for example, the opaque area in a data line of the thin film transistor of the COA substrate.

In the embodiment, since the through hole is filled with the material of the black matrix, the inside of the through hole has no unnecessary space, and no air bubbles stay inside the COA substrate. This is advantageous in that the air bubbles are volatilized, which improves the display effect. In the embodiment, since the black matrix is formed on the second passivation layer, meaning the through hole is filled and the black matrix is formed, the manufacturing process is saved.

In the present invention, the through hole is filled while the black matrix is formed, which avoids air bubbles being reserved, thereby improving the display effect and reducing manufacturing costs.

Refer now to FIG. 4, which is a structural schematic view of a COA substrate according to a second embodiment of the present invention.

The COA substrate according to this embodiment is basically the same as the COA substrate according to the second embodiment, but the difference being as follows:

A surface of the COA substrate is simultaneously provided with a black matrix 42 and a spacer 43, wherein the through hole is filled with the material of the black matrix.

The manufacturing method of the COA substrate according to this embodiment is basically the same as the COA substrate according to the second embodiment, but the difference being as follows: in the specific step S402 of step S3011, the black matrix is formed by graphing the material of the black matrix, but in this embodiment, the step is:

S403: forming the black matrix and the spacer simultaneously by graphing the material of the black matrix.

Since the material of the black matrix is usually a photoresist, and the material of the spacer is also a photoresist, the material of the black matrix can be used to manufacture the space. The black matrix is exposed, developed, and etched to form the black matrix and the spacer by a mask, wherein the graphs of the mask include the graphs of the spacer and the graphs of the black matrix. The black matrix and the spacer are formed in an opaque area, for example, the opaque area is in a data line of the thin film transistor of the COA substrate.

In the present invention, the through hole is filled while the black matrix and the spacer are formed, which avoids air bubbles being reserved, thereby improving the display effect and reducing manufacturing costs.

The present invention has been described with preferred embodiments thereof and it is understood that many changes and modifications to the described embodiment can be carried out without departing from the scope and the spirit of the invention that is intended to be limited only by the appended claims.

1. A color filter on array (COA) substrate, comprising:
a substrate;
a first metal layer positioned on the substrate and comprising a gate electrode area of a thin film transistor;
a gate insulation layer partially positioned on the first metal layer and used to separate the first metal layer and a second metal layer;
an active layer partially positioned on the gate insulation layer and used to form a channel;
an ohmic contact layer positioned on the active layer;
the second metal layer positioned on the ohmic contact layer and comprising a drain electrode area and a source electrode of the thin film transistor;
a first passivation layer positioned on the second metal layer and used to separate the second metal layer and a color resist layer;
the color resist layer positioned on the first passivation layer and used to form color resists;
a second passivation layer positioned on the color resist layer and including a through hole to be connected to the drain electrode of the second metal layer;
a transparent conductive layer positioned on the second passivation layer and inside the through hole; and
a spacer positioned on a surface of the COA substrate, wherein a material of the spacer is filled into the through hole.

2. The COA substrate according to claim 1, wherein a predetermine amount of the material of the spacer is filled into the through hole, so that the predetermine amount of the material of the spacer is used to flatten the surface of the COA substrate.

3. The COA substrate according to claim 1, wherein the surface of the COA substrate is provided with the material of the spacer, and the material of the spacer is used to formed the spacer.

4. The COA substrate according to claim 1, wherein the material of the second passivation layer is an organic and transparent material.

5. A manufacturing method of a color filter on array (COA) substrate, comprising:
forming a first metal layer on a substrate, and graphing the first metal layer to form a gate electrode;
forming a gate insulation layer on the gate electrode and parts of the substrate which is uncovered by the gate electrode;
forming an active layer on the gate insulation layer;
forming an ohmic contact layer on the active layer;
forming a second metal layer on the ohmic contact layer, and graphing the second metal layer to form a drain electrode and a source electrode;
forming a first passivation layer on the second metal layer;
forming a color resist layer on the first passivation layer;
forming a second passivation layer on the color resist layer;
forming a through hole on the second passivation layer to connect the drain electrode;
forming a transparent conductive layer on the second passivation layer and inside the through hole; and
forming a black matrix on a surface of the COA substrate and filling a material of the black matrix inside the through hole.

6. The manufacturing method of the COA substrate according to claim 5, wherein the step of filling a material of the black matrix inside the through hole includes: filling a material of the black matrix inside the through hole until the surface of the COA substrate is flat.

7. The manufacturing method of the COA substrate according to claim 5, wherein the step of forming a black matrix on a surface of the COA substrate includes: coating the material of the black matrix on the surface of the COA substrate; and forming the black matrix by graphing the material of the black matrix.

8. The manufacturing method of the COA substrate according to claim 5, wherein after the step of forming a transparent conductive layer on the second passivation layer and inside the through hole, the method further includes:
forming a spacer and a black matrix on the surface of the COA substrate;
and filling the material of the black matrix into the through hole.

9. The manufacturing method of the COA substrate according to claim 8, wherein the step of forming a spacer and a black matrix on the surface of the COA substrate includes: coating the material of the black matrix on the surface of the COA substrate; and forming the black matrix by graphing the material of the black matrix.

10. The manufacturing method of the COA substrate according to claim 5, wherein the step of forming a second passivation layer on the color resist layer includes: forming the second passivation layer on the color resist layer by a coating method, wherein the material of the second passivation layer is an organic and transparent material.

11. A color filter on array (COA) substrate, comprising:
a substrate;
a first metal layer positioned on the substrate and comprising a gate electrode area of a thin film transistor;
a gate insulation layer partially positioned on the first metal layer and used to separate the first metal layer and a second metal layer;
an active layer partially positioned on the gate insulation layer and used to form a channel;
an ohmic contact layer positioned on the active layer;
the second metal layer positioned on the ohmic contact layer and comprising a drain electrode area and a source electrode of the thin film transistor;
a first passivation layer positioned on the second metal layer and used to separate the second metal layer and a color resist layer;
the color resist layer positioned on the first passivation layer and used to form color resists;
a second passivation layer positioned on the color resist layer and including a through hole to be connected to the drain electrode of the second metal layer;
a transparent conductive layer positioned on the second passivation layer and inside the through hole; and
a spacer and a black matrix positioned on a surface of the COA substrate, wherein a material of the black matrix is filled into the through hole.

12. The COA substrate according to claim 11, wherein a predetermine amount of the material of the black matrix is filled into the through hole, so that the predetermine amount of the material of the black matrix is used to flatten the surface of the COA substrate.

13. The COA substrate according to claim 11, wherein the surface of the COA substrate is provided with the material of the black matrix, and the material of the black matrix is used to formed the spacer.

14. The COA substrate according to claim 11, wherein the material of the second passivation layer is an organic and transparent material.

15. The COA substrate according to claim 11, wherein the material of the black matrix is a black photoresist.
